(19) United States
(12) Patent Application Publication
(10) Pub. No.: US 2023/0171967 A1
(43) Pub. Date: Jun. 1, 2023

(54) SEMICONDUCTOR DEVICE AND METHOD FOR FABRICATING THE SAME

(71) Applicant: SK hynix Inc., Icheon-si (KR)

(72) Inventors: Cha Deok DONG, Icheon-si (KR); Keo Rock CHOI, Icheon-si (KR); Guk Cheon KIM, Icheon-si (KR)

(21) Appl. No.: 17/903,907

(22) Filed: Sep. 6, 2022

(30) Foreign Application Priority Data
Nov. 29, 2021 (KR) 10-2021-0167633

(51) Int. Cl. H01L 27/22; H01L 43/02; H01L 43/12

(52) U.S. Cl. CPC H01L 27/224; H01L 43/02; H01L 43/12

(57) ABSTRACT

A semiconductor device may include: a memory cell disposed over a substrate and including a variable resistance layer and a selector layer; a protection layer disposed on side surfaces of the memory cell and an upper surface of the substrate on which the memory cell is not disposed; and a first encapsulation layer disposed on the memory cell and the protection layer, wherein the protection layer may include a treated surface that is modified by a material including helium.

### PRIORITY CLAIM AND CROSS-REFERENCE TO RELATED APPLICATION

This patent document claims the priority and benefits of Korean Patent Application No. 10-2021-0167633 filed on Nov. 29, 2021, which is incorporated herein by reference in its entirety.

### TECHNICAL FIELD

This patent document relates to memory circuits or devices and their applications in electronic devices or systems.

### BACKGROUND

The recent trend toward miniaturization, low power consumption, high performance, and multi-functionality in the electrical and electronics industry has compelled the semiconductor manufacturers to focus on high-performance, high capacity semiconductor devices. Examples of such high-performance, high capacity semiconductor devices include memory devices that can store data by switching between different resistance states according to an applied voltage or current. The semiconductor devices may include an RRAM (resistive random access memory), a PRAM (phase change random access memory), an FRAM (ferroelectric random access memory), an MRAM (magnetic random access memory), and an electronic fuse (E-fuse).

### SUMMARY

The disclosed technology in this patent document includes memory circuits or devices and their applications in semiconductor devices or systems and various implementations of a semiconductor device that can improve the performance of a semiconductor device and reduce manufacturing defects.

In one aspect, a semiconductor device may include: a memory cell disposed over a substrate and including a variable resistance layer and a selector layer; a protection layer disposed on side surfaces of the memory cell and an upper surface of the substrate on which the memory cell is not disposed; and a first encapsulation layer disposed on the memory cell and the protection layer, wherein the protection layer may include a treated surface that is modified by a material including helium.

In another aspect, a method for fabricating a semiconductor device may include: forming a memory cell over a substrate, the memory cell including a variable resistance layer and a selector layer;

forming a protection layer on the memory cell and the substrate on which the memory cell is not disposed by performing a first helium treatment process on the memory cell; and forming a first encapsulation layer on the memory cell and the protection layer

In another aspect, a method for fabricating a semiconductor device including a memory cell structured to include a variable resistance layer and a selector layer, the method may include: forming a first material layer for forming a first portion of the memory cell over a substrate; forming a second portion of the memory cell by forming a second material layer on the first material layer and etching the second material layer; forming an initial sidewall spacer layer on the resultant structure; forming the first portion of the memory cell by etching the first material layer using the initial sidewall spacer layer, wherein the initial sidewall spacer layer remains after the etching of the first material layer as a sidewall spacer layer on side surfaces of the second portion; forming a protection layer on the memory cell and the substrate by performing a first helium treatment process on the memory cell; and forming a first encapsulation layer on the memory cell and the protection layer.

### BRIEF DESCRIPTION OF THE DRAWINGS

FIGS. 1A and 1B illustrate a semiconductor device based on some implementations of the disclosed technology.

FIG. 2 illustrates an example of a magnetic tunnel junction (MTJ) structure included in a variable resistance layer based on some implementations of the disclosed technology.

FIGS. 3A to 3D are cross-sectional views illustrating an example method for fabricating a semiconductor device based on some implementations of the disclosed technology.

FIGS. 4A to 4I are cross-sectional views illustrating another example method for fabricating a semiconductor device based on some implementations of the disclosed technology.

FIGS. 5A to 5F are cross-sectional views illustrating another example method for fabricating a semiconductor device based on some implementations of the disclosed technology.

FIG. 6 illustrate a semiconductor device based on some implementations of the disclosed technology.

### DETAILED DESCRIPTION

Hereinafter, various embodiments of the disclosure will be described in detail with reference to the accompanying drawings.

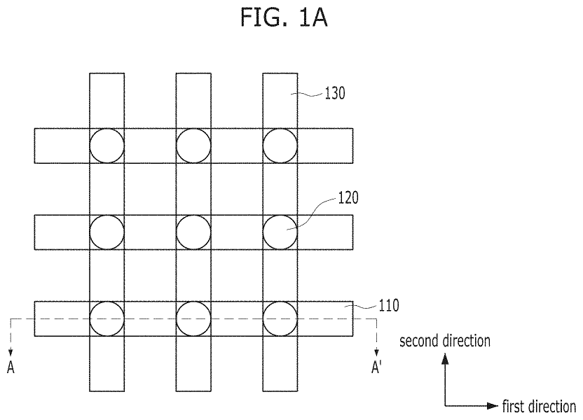

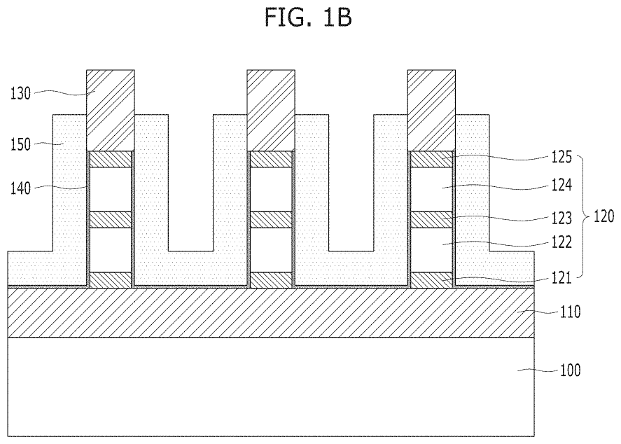

FIGS. 1A and 1B illustrate a semiconductor device based on some implementations of the disclosed technology. FIG. 1A is a plan view, and FIG. 1B is a cross-sectional view taken along line A-A′ of FIG. 1A.

Referring to FIGS. 1A and 1B, the semiconductor device may include a cross-point structure including a substrate 100, first conductive lines 110 formed over the substrate 100 and extending in a first direction, second conductive lines 130 formed over the first conductive lines 110 to be spaced apart from the first conductive lines 110 and extending in a second direction crossing the first direction, memory cells 120 disposed at intersections of the first conductive lines 110 and the second conductive lines 130 between the first conductive lines 110, the second conductive lines 130, a protection layer 140 and an encapsulation layer 150.

The substrate 100 may include a semiconductor material such as silicon. A required lower structure (not shown) may be formed in the substrate 100. For example, the substrate 100 may include a driving circuit (not shown) electrically connected to the first conductive lines 110 and/or the second conductive lines 130 to control operations of the memory cells 120. In this patent document, the conductive lines can indicate conductive structures that electrically connect two or more circuit elements in the semiconductor device. In some implementations, the conductive lines include word lines that are used control access to memory cells in the memory device and bit lines that are used to read out information stored in the memory cells. In some implementations, the conductive lines include interconnects that carry signals between different circuit elements in the semiconductor device.

The first conductive lines 110 and the second conductive lines 130 may be connected to a lower end and an upper end of the memory cell 120, respectively, and may provide a voltage or a current to the memory cell 120 to drive the memory cell 120. When the first conductive lines 110 functions as a word line, the second conductive lines 130 may function as a bit line. Conversely, when the first conductive lines 110 functions as a bit line, the second conductive lines 130 may function as a word line. The first conductive lines 110 and the second conductive lines 130 may include a single-layer or multilayer structure including one or more of various conductive materials. Examples of the conductive materials may include a metal, a metal nitride, or a conductive carbon material, or a combination thereof, but are not limited thereto. For example, the first conductive lines 110 and the second conductive lines 130 may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The memory cell 120 may be arranged in a matrix having rows and columns along the first direction and the second direction so as to overlap the intersection regions between the first conductive lines 110 and the second conductive lines 130. In an implementation, each of the memory cells 120 may have a size that is substantially equal to or smaller than that of the intersection region between each corresponding pair of the first conductive lines 110 and the second conductive lines 130. In another implementation, each of the memory cells 120 may have a size that is larger than that of the intersection region between each corresponding pair of the first conductive lines 110 and the second conductive lines 130.

Spaces between the first conductive lines 110, the second conductive lines 130 and the memory cell 120 may be filled with an insulating material.

The memory cell 120 may include a stacked structure including a lower electrode layer 121, a selector layer 122, a middle electrode layer 123, a variable resistance layer 124 and an upper electrode layer 125.

The lower electrode layer 121 may be interposed between the first conductive line 110 and the selector layer 122 and disposed at a lowermost portion of each of the memory cells 120. The lower electrode layer 121 may function as a circuit node that carries a voltage or a current between a corresponding one of the first conductive lines 110 and the remaining portion (e.g., the elements 122, 123, 124 and 125) of each of the memory cells 120. The middle electrode layer 123 may be interposed between the selector layer 122 and the variable resistance layer 124. The middle electrode layer 123 may electrically connect the selector layer 122 and the variable resistance layer 124 to each other while physically separating the selector layer 122 and the variable resistance layer 124 from each other. The upper electrode layer 125 may be disposed at an uppermost portion of the memory cell 120 and function as a transmission path of a voltage or a current between the rest of the memory cell 120 and a corresponding one of the second conductive lines 130.

The lower electrode layer 121, the middle electrode layer 123 and the upper electrode layer 125 may include a single-layer or multilayer structure including various conductive materials such as a metal, a metal nitride, a conductive carbon material, or a combination thereof, respectively. For example, the lower electrode layer 121, the middle electrode layer 123 and the upper electrode layer 125 may include tungsten (W), titanium (Ti), tantalum (Ta), platinum (Pt), aluminum (Al), copper (Cu), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The lower electrode layer 121, the middle electrode layer 123 and the upper electrode layer 125 may include the same material as each other or different materials from each other.

The lower electrode layer 121, the middle electrode layer 123 and the upper electrode layer 125 may have the same thickness as each other or different thicknesses from each other.

The selector layer 122 may function to reduce and/or suppress a leakage current between the memory cells 120 sharing the first conductive lines 110 or the second conductive lines 130. To this end, the selector layer 122 may have a threshold switching characteristic that blocks or substantially limits a current when a magnitude of an applied voltage is less than a predetermined threshold value and allows the current to increase rapidly when the magnitude of the applied voltage is equal to or greater than the predetermined threshold value. This threshold value may be referred to as a threshold voltage, and the selector layer 122 may be controlled to be in either a turned-on or “on” state to be electrically conductive or a turned-off or “off” state to be electrically less-conductive than the “on” state or electrically non-conductive depending on whether the applied voltage is above or below the threshold voltage. Thus, the selector layer 122 exhibits different electrically conductive states to provide a switching operation to switch between the different electrically conductive states by controlling the applied voltage relative to the threshold voltage. The selector layer 122 may include an MIT (Metal Insulator Transition) material such as NbO₂, TiO₂, VO₂, WO₂, or others, an MIEC (Mixed Ion-Electron Conducting) material such as ZrO₂(Y₂O₃), Bi₂O₃—BaO, (La₂O₃)x(CeO₂)₁₋ₓ, or others, an OTS (Ovonic Threshold Switching) material including chalcogenide material such as Ge₂Sb₂Te₅, As₂Te₃, As₂, As₂Se₃, or others, or a tunneling insulating material such as silicon oxide, silicon nitride, a metal oxide, or others. A thickness of the tunneling insulating layer is sufficiently small to allow tunneling of electrons under a given voltage or a given current. The selector layer 122 may include a single-layer or multilayer structure.

In some implementations, the selector layer 122 may perform a threshold switching operation through a doped region formed in a material layer for the selector layer 122. Thus, a size of the threshold switching operation region may be controlled by a distribution area of the dopants. The dopants may form trap sites for charge carriers in the material layer for the selector layer 122. The trap sites may capture the charge carriers moving in the selector layer 122 based on an external voltage applied to the selector layer 122. The trap sites thereby provide a threshold switching characteristic and are used to perform a threshold switching operation.

In some implementations, the selector layer 122 may include a dielectric material having incorporated dopants. The selector layer 122 may include an oxide with dopants, a nitride with dopants, or an oxynitride with dopants, or a combination thereof such as silicon oxide, titanium oxide, aluminum oxide, tungsten oxide, hafnium oxide, tantalum oxide, niobium oxide, silicon nitride, titanium nitride, aluminum nitride, tungsten nitride, hafnium nitride, tantalum nitride, niobium nitride, silicon oxynitride, titanium oxynitride, aluminum oxynitride, tungsten oxynitride, hafnium oxynitride, tantalum oxynitride, or niobium oxynitride, or a combination thereof. The dopants doped into the selector layer 122 may include an n-type dopant or a p-type dopant and be incorporated for example, by ion implantation process. Examples of the dopants may include one or more of boron (B), nitrogen (N), carbon (C), phosphorous (P), arsenic (As), aluminum (Al), silicon (Si) and germanium (Ge). For example, the selector layer 122 may include As-doped silicon oxide or Ge-doped silicon oxide.

The variable resistance layer 124 may be used to store data by switching between different resistance states (e.g., high and low resistance states to represent digital level “1” and “0” or vice versa) according to an applied voltage or current. The variable resistance layer 124 may have a single-layered structure or a multi-layered structure including at least one of materials having a variable resistance characteristic used for an RRAM, a PRAM, an MRAM, an FRAM, and others. For example, the variable resistance layer 124 may include a metal oxide such as a transition metal oxide or a perovskite-based oxide, a phase change material such as a chalcogenide-based material, a ferromagnetic material, a ferroelectric material, or others. However, the implementations are not limited thereto, and the memory cell 120 may include other memory layers capable of storing data in various ways instead of the variable resistance layer 124.

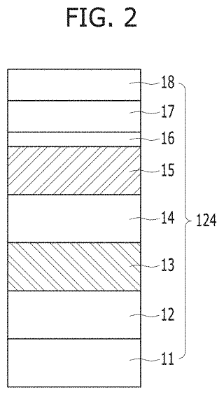

In some implementations, the variable resistance layer 124 may include a magnetic tunnel junction (MTJ) structure. This will be explained with reference to FIG. 2.

In some implementations, the variable resistance layer 124 may include a magnetic tunnel junction (MTJ) structure. FIG. 2 illustrates an example of a magnetic tunnel junction (MTJ) structure included in a variable resistance layer based on some implementations of the disclosed technology.

The variable resistance layer 124 may include an MTJ structure including a free layer 13 having a variable magnetization direction, a pinned layer 15 having a pinned magnetization direction and a tunnel barrier layer 14 interposed between the free layer 13 and the pinned layer 15.

The free layer 13 may have one of different magnetization directions or one of different spin directions of electrons to switch the polarity of the free layer 13 in the MTJ structure, resulting in changes in resistance value. In some implementations, the polarity of the free layer 13 is changed or flipped upon application of a voltage or current signal (e.g., a driving current above a certain threshold) to the MTJ structure. With the polarity changes of the free layer 13, the free layer 13 and the pinned layer 15 have different magnetization directions or different spin directions of electron, which allows the variable resistance layer 124 to store different data or represent different data bits. The free layer 13 may also be referred to as a storage layer. The magnetization direction of the free layer 13 may be substantially perpendicular to a surface of the free layer 13, the tunnel barrier layer 14 and the pinned layer 15. In other words, the magnetization direction of the free layer 13 may be substantially parallel to stacking directions of the free layer 13, the tunnel barrier layer 14 and the pinned layer 15. Therefore, the magnetization direction of the free layer 13 may be changed between a downward direction and an upward direction. The change in the magnetization direction of the free layer 13 may be induced by a spin transfer torque generated by an applied current or voltage.

The free layer 13 may have a single-layer or multilayer structure including a ferromagnetic material. For example, the free layer 13 may include an alloy based on Fe, Ni or Co, for example, an Fe—Pt alloy, an Fe—Pd alloy, a Co—Pd alloy, a Co—Pt alloy, a Co—Fe alloy, an Fe—Ni—Pt alloy, a Co—Fe—Pt alloy, a Co—Ni—Pt alloy, or a Co—Fe—B alloy, or others, or may include a stack of metals, such as Co/Pt, or Co/Pd, or others.

The tunnel barrier layer 14 may allow the tunneling of electrons in both data reading and data writing operations. In a write operation for storing new data, a high write current may be directed through the tunnel barrier layer 14 to change the magnetization direction of the free layer 13 and thus to change the resistance state of the MTJ for writing a new data bit. In a reading operation, a low reading current may be directed through the tunnel barrier layer 14 without changing the magnetization direction of the free layer 13 to measure the existing resistance state of the MTJ under the existing magnetization direction of the free layer 13 to read the stored data bit in the MTJ. The tunnel barrier layer 14 may include a dielectric oxide such as MgO, CaO, SrO, TiO, VO, or NbO or others.

The pinned layer 15 may have a pinned magnetization direction, which remains unchanged while the magnetization direction of the free layer 13 changes. The pinned layer 15 may be referred to as a reference layer. In some implementations, the magnetization direction of the pinned layer 15 may be pinned in a downward direction. In some implementations, the magnetization direction of the pinned layer 15 may be pinned in an upward direction.

The pinned layer 15 may have a single-layer or multilayer structure including a ferromagnetic material. For example, the pinned layer 15 may include an alloy based on Fe, Ni or Co, for example, an Fe—Pt alloy, an Fe—Pd alloy, a Co—Pd alloy, a Co—Pt alloy, a Co—Fe alloy, an Fe—Ni—Pt alloy, a Co—Fe—Pt alloy, a Co—Ni—Pt alloy, or a Co—Fe—B alloy, or may include a stack of metals, such as Co/Pt, or Co/Pd or others.

If a voltage or current is applied to the variable resistance layer 124, the magnetization direction of the free layer 13 may be changed by spin torque transfer. In some implementations, when the magnetization directions of the free layer 13 and the pinned layer 15 are parallel to each other, the variable resistance layer 124 may be in a low resistance state, and this may indicate digital data bit “0.” Conversely, when the magnetization directions of the free layer 13 and the pinned layer 15 are anti-parallel to each other, the variable resistance layer 124 may be in a high resistance state, and this may indicate a digital data bit “1.” In some implementations, the variable resistance layer 124 can be configured to store data bit ‘1’ when the magnetization directions of the free layer 13 and the pinned layer 15 are parallel to each other and to store data bit ‘0’ when the magnetization directions of the free layer 13 and the pinned layer 15 are anti-parallel to each other.

In some implementations, the variable resistance layer 124 may further include one or more layers performing various functions to improve a characteristic of the MTJ structure. For example, the variable resistance layer 124 may further include at least one of a buffer layer 11, an under layer 12, a spacer layer 16, a magnetic correction layer 17 and a capping layer 18.

The under layer 12 may be disposed under the free layer 13 and serve to improve perpendicular magnetic crystalline anisotropy of the free layer 13. The under layer 12 may have a single-layer or multilayer structure including a metal, a metal alloy, a metal nitride, or a metal oxide, or a combination thereof.

The buffer layer 11 may be disposed below the under layer 12 to facilitate crystal growth of the under layer 12, thus improving perpendicular magnetic crystalline anisotropy of the free layer 13. The buffer layer 11 may have a single-layer or multilayer structure including a metal, a metal alloy, a metal nitride, or a metal oxide, or a combination thereof. Moreover, the buffer layer 11 may be formed of or include a material having a good compatibility with a bottom electrode (not shown) in order to resolve the lattice constant mismatch between the bottom electrode and the under layer 12. For example, the buffer layer 11 may include tantalum (Ta).

The spacer layer 16 may be interposed between the magnetic correction layer 17 and the pinned layer 15 and function as a buffer between the magnetic correction layer 17 and the pinned layer 15. The spacer layer 16 may be used to improve characteristics of the magnetic correction layer 17. The spacer layer 16 may include a noble metal such as ruthenium (Ru).

The magnetic correction layer 17 may be used to offset the effect of the stray magnetic field produced by the pinned layer 15. In this case, the effect of the stray magnetic field of the pinned layer 15 can decrease, and thus a biased magnetic field in the free layer 13 can decrease. The magnetic correction layer 17 may have a magnetization direction anti-parallel to the magnetization direction of the pinned layer 15. In the implementation, when the pinned layer 15 has a downward magnetization direction, the magnetic correction layer 17 may have an upward magnetization direction. Conversely, when the pinned layer 15 has an upward magnetization direction, the magnetic correction layer 17 may have a downward magnetization direction. The magnetic correction layer 17 may be exchange coupled with the pinned layer 15 via the spacer layer 16 to form a synthetic anti-ferromagnet (SAF) structure. The magnetic correction layer 17 may have a single-layer or multilayer structure including a ferromagnetic material.

In this implementation, the magnetic correction layer 17 is located above the pinned layer 15, but the magnetic correction layer 17 may disposed at a different location. For example, the magnetic correction layer 17 may be located above, below, or next to the MTJ structure while the magnetic correction layer 17 is patterned separately from the MTJ structure.

The capping layer 18 may be used to protect the variable resistance layer 124 and/or function as a hard mask for patterning the variable resistance layer 124. In some implementations, the capping layer 18 may include various conductive materials such as a metal. In some implementations, the capping layer 18 may include a metallic material having almost none or a small number of pin holes and high resistance to wet and/or dry etching. In some implementations, the capping layer 18 may include a metal, a nitride, or an oxide, or a combination thereof. For example, the capping layer 18 may include a noble metal such as ruthenium (Ru).

The capping layer 18 may have a single-layer or multilayer structure. In some implementations, the capping layer 18 may have a multilayer structure including an oxide, or a metal, or a combination thereof. For example, the capping layer 18 may have a multilayer structure of an oxide layer, a first metal layer and a second metal layer.

A material layer (not shown) for resolving the lattice structure differences and the lattice constant mismatch between the pinned layer 15 and the magnetic correction layer 17 may be interposed between the pinned layer 15 and the magnetic correction layer 17. For example, this material layer may be amorphous and may include a metal a metal nitride, or metal oxide.

In some implementations, each of the memory cells 120 includes the lower electrode layer 121, the selector layer 122, the middle electrode layer 123, the variable resistance layer 124 and the upper electrode layer 125. However, the memory cells 120 may have different structures. In some implementations, the relative positions of the selector layer 122 and the variable resistance layer 124 may be reversed. In some implementations, at least one of the lower electrode layer 121, the middle electrode layer 123 and the upper electrode layer 125 may be omitted. In some implementations, in addition to the layers 121 to 125 shown in FIG. 1B, the memory cells 120 may further include one or more layers (not shown) for enhancing characteristics of the memory cells 120 or improving fabricating processes.

In some implementations, neighboring memory cells of the plurality of memory cells 120 may be spaced apart from each other at a predetermined interval, and trenches may be present between the plurality of memory cells 120. A trench between neighboring memory cells 120 may have a height to width ratio (i.e., an aspect ratio) in a range from 1:1 to 40:1, from 10:1 to 40:1, from 10:1 to 20:1, from 5:1 to 10:1, from 10:1 to 15:1, from 1:1 to 25:1, from 1:1 to 30:1, from 1:1 to 35:1, or from 1:1 to 45:1.

In some implementations, the trench may have sidewalls that are substantially perpendicular to an upper surface of the substrate 100. In some implementations, neighboring trenches may be spaced apart from each other by an equal or similar distance.

To form a high-density cross-point array, the variable resistance layer 124 and the selector layer 122 have been usually formed on an upper portion and a lower portion of the same element. The variable resistance layer 124 and the selector layer 122 may be formed by depositing material layers for forming the variable resistance layer 124 and the selector layer 122 and etching the material layers by performing patterning processes. The variable resistance layer 124 including MTJ has a stacked structure of various materials. The variable resistance layer 124 and the selector layer 122 include very sensitive materials which influence the basic characteristic of the element. It is often the case that characteristics of the variable resistance layer 124 and the selector layer 122 may be deteriorated by an influence from a subsequent process or adjacent layers. For example, when the variable resistance layer 124 includes MTJ, a dead layer may occur due to diffusion of materials (for example, N, H, F, N—H, or others) induced during deposition of external films and thus the magnetic properties of MTJ may be deteriorated. Further, when the selector layer 122 includes a dielectric material with a dopant, the dopant may be lost by a subsequent process.

The semiconductor device may further include an encapsulation layer 150 to protect the memory cell 120 from external influences.

The encapsulation layer 150 may serve to block a physical influence from the outside and function as a stop barrier for forming a second conductive lines 130.

The encapsulation layer 150 may be formed at a predetermined thickness to control a damage of the variable resistance layer 124 during forming the second conductive lines 130.

The encapsulation layer 150 may include a dielectric material. The dielectric material may include an oxide, a nitride, or a combination thereof. For example, the encapsulation layer 150 may include SiO₂, SiN₄, SiOCN, SiON, or a combination thereof.

The encapsulation layer 150 may be formed over the entire memory cell 120 including the selector layer 122 and the variable resistance layer 124 at once. As described above, since the selector layer 122 and the variable resistance layer 124 have different characteristics from each other, it is difficult to prevent degradation of properties of both the selector layer 122 and the variable resistance layer 124 by one encapsulation layer 150. That is, the encapsulation layer 150 has different effects on the selector layer 122 and the variable resistance layer 124 depending on the deposition conditions. Therefore, even if deterioration of properties of the selector layer 122 may be prevented, properties of the variable resistance layer 124 may be deteriorated, or even if deterioration of properties of the variable resistance layer 124 may be prevented, properties of the selector layer 122 may be deteriorated. For example, in case of a nitride film deposited using a high RF power of 3000 W or more, crystallization of the MTJ included in the resistance layer 124 may be improved, but dopant loss in the selector layer 122 may occur. Further, in case of an N-rich nitride film deposited using a low RF power and a mixed gas of SiH₄ and NH₃, a switching characteristic of the selector layer 122 may be stabilized by incorporating nitrogen into the selector layer 122, but magnetic characteristics of the MTJ included in the variable resistance layer 124, especially a coercive force (Hc) characteristic of the free layer 13 may be deteriorated by absorbing nitrogen into the magnetic materials. As a result, the encapsulation layer 150 does not serve to protect the memory cell 120 from external influences, but rather may deteriorate any one of characteristics of the selector layer 122 or the variable resistance layer 124.

In order to overcome these problems, in implementations of the disclosed technology, the protection layer 140 may be formed by performing a helium treatment process before forming the encapsulation layer 150 covering the memory cell 120 so that the adverse effect of the encapsulation layer 150 can be reduced or prevented. In some implementations, the helium treatment process may include applying helium to the surface of a certain material layer. In some implementations, the helium treatment process may be used to prevent deterioration of characteristics of the selector layer 122 and the variable resistance layer 124 and maintain the original characteristics of the selector layer 122 and the variable resistance layer 124.

The protection layer 140 may be formed by helium treatment. A physical thickness of the protection layer 140 may be very thin. When the helium treatment is performed on the memory cell 120, plasma generated from a helium gas may induce atomic migration on a surface of the memory cell 120 to modify the surface morphology or profile to be very flat. That is, the protection layer 140 may include a layer that is formed by modifying the surface morphology or profile using the helium treatment process.

In some implementations, the protection layer 140 may be formed on side surfaces of the memory cell 120 and an upper surface of the first conductive lines 110.

As such, it is possible to prevent diffusion of elements or materials from the outside to the memory cell 120 by forming the protection layer 140 through the helium treatment. Thus, formation of the dead layers in the MTJ included in the variable resistance layer 124 can be prevented, the crystal structure can be completely maintained, and reliability can be improved by strengthening resistance. Further, by preventing energy transfer by a RF power when the encapsulation layer 150 is subsequently formed, dopant loss in the selector layer 122 can be reduced, thereby minimizing an operation current and preventing deformation of the selector layer 122. In addition, intermixing between the memory cell 120 and the encapsulation layer 150 can be suppressed, which is advantageous in fabricating a small device according to scaling down.

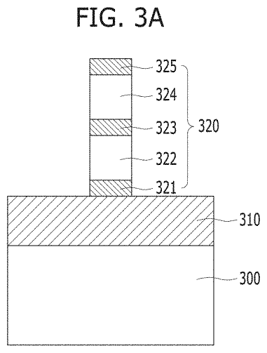

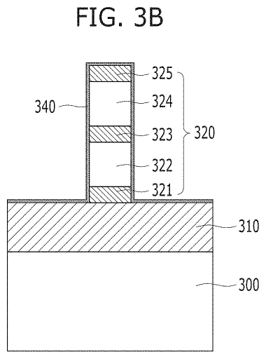

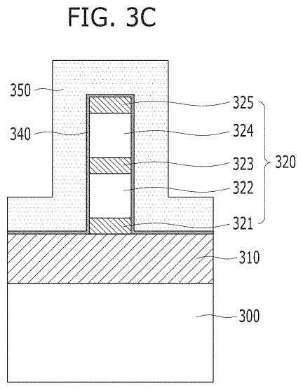

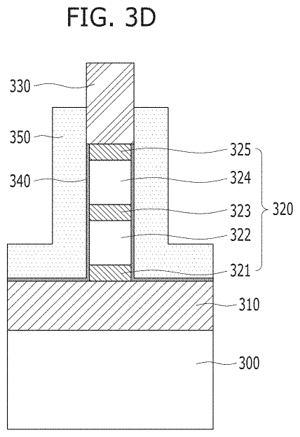

The helium treatment used for formation of the protection layer 140 may be a simple process that does not affect the structure of the deposited layers. The helium treatment process may be performed several times as needed and may not cause side effects such as etch rate fluctuation. The helium treatment will be described with reference to FIGS. 3A to 3D, FIGS. 4A to 4I and FIGS. 5A to 5F.

Although one cross-point structure has been described, two or more cross-point structures may be stacked in a vertical direction perpendicular to a top surface of the substrate 100.

A method for fabricating a semiconductor device will be explained with reference to FIGS. 3A to 3D. The detailed descriptions similar to those described in the implementation of FIGS. 1A, 1B and 2 will be omitted.

Referring to FIG. 3A, first conductive lines 310 may be formed over a substrate 300 in which a predetermined structure is formed. For example, the first conductive lines 310 may be formed by forming a dielectric layer (not shown) having a trench for forming the first conductive lines 310 over the substrate 300, forming a conductive layer for the first conductive lines 310 and etching the conductive layer using a mask pattern in a line shape extending in a first direction.

A memory cell 320 may be formed over the first conductive lines 310. The memory cell 320 may be formed by forming a material layer for a lower electrode layer 321, a material layer for a selector layer 322, a material layer for a middle electrode layer 323, a material layer for a variable resistance layer 324 and a material layer for an upper electrode layer 325 and etching the material layers using a mask pattern.

Referring to FIG. 3B, a helium treatment process may be performed on the memory cell 320.

The helium treatment process may be performed under a condition of a flow rate of a helium gas of 5-1000 cubic centimeters per minute (sccm), a RF (radio frequency) power of 100-5000 W, and a temperature of 25-350° C. In some implementations, the helium treatment process may include applying helium to the surface of a certain material layer under the condition discussed above.

The helium treatment may be a simple process that does not affect the structure of the deposited layers. The helium treatment process may be performed several times as needed and may not cause side effects such as etch rate fluctuation.

By performing the helium treatment on the memory cell 320, plasma generated from a helium gas may induce the movement of atoms on the surface of the memory cell 320 so that the surface morphology or profile may become very flattened. The layer obtained by modifying the surface morphology or profile by the helium treatment may be referred to as a protection layer 340. The physical thickness of the protection layer 340 may be very thin. By modifying the surface morphology or profile of the memory cell 320 through the helium treatment, it is possible to prevent diffusion of atoms from the outside to the memory cell 320 and energy transfer to the memory cell 320 by the RF power in a subsequent process of forming an encapsulating layer (see, reference numeral 350 of FIG. 3C).

The protection layer 340 may be formed on an upper surface and side surfaces of the memory cell 320, and an upper surface of the first conductive lines 310.

Referring to FIG. 3C, the encapsulation layer 350 may be conformally formed on the structure of FIG. 3B.

The encapsulation layer 350 may include a dielectric material. The dielectric material may include an oxide, a nitride, or a combination thereof. For example, the encapsulation layer 350 may include SiO₂, SiN₄, SiOCN, SiON, or a combination thereof.

The encapsulation layer 350 may be formed at a predetermined thickness to control a damage of the variable resistance layer 324 during forming a second conductive lines 330.

Referring to FIG. 3D, the second conductive lines 330 may be formed on the memory cell 320.

For example, the second conductive lines 330 may be formed by forming a dielectric layer (not shown) having a trench for forming the second conductive lines 330, forming a conductive layer for forming second conductive lines 330 in the trench, and etching the conductive layer using a mask pattern in a line shape extending in a second direction. At this time, a portion of the protection layer 340 and a portion of the encapsulation layer 350 disposed on the upper electrode layer 325 may be removed.

Through the processes as described above, the semiconductor device including the first conductive lines 310, the memory cell 320, the second conductive lines 330, the protection layer 340 and the encapsulation layer 350 may be formed. The memory cell 320 may include the lower electrode layer 321, the selector layer 322, the middle electrode layer 323, the variable resistance layer 324 and the upper electrode layer 325 which are sequentially stacked. The protection layer 340 may be formed on the side surfaces of the memory cell 320 and the upper surface of the conductive lines 310.

In some implementations, the protection layer 340 in which the surface morphology is modified may be formed by performing the helium treatment process on the memory cell 320 before forming the encapsulation layer 350. Thus, it is possible to reduce the adverse effect of the encapsulation layer 350 on the selector layer 322 or the variable resistance layer 324. Therefore, it is possible to prevent deterioration of characteristics of the selector layer 322 and variable resistance layer 324 and maintain the original characteristics of the selector layer 322 and the variable resistance layer 324. By performing the helium treatment process before forming the encapsulation layer 350, it is possible to prevent diffusion of elements or materials from the outside to the variable resistance layer 324. Accordingly, formation of the dead layers in the variable resistance layer 124 can be prevented, the crystal structure can be completely maintained, and reliability can be improved by strengthening resistance. Further, by preventing energy transfer by a RF power when the encapsulation layer 350 is subsequently formed, dopant loss in the selector layer 322 can be reduced, thereby minimizing an operation current and preventing deformation of the selector layer 322. In addition, intermixing between the memory cell 320 and the encapsulation layer 350 can be suppressed by the protection layer 340.

The substrate 300, the first conductive lines 310, the memory cell 320, the lower electrode layer 321, the selector layer 322, the middle electrode layer 323, the variable resistance layer 324, the upper electrode layer 325, the second conductive lines 330, the protection layer 340 and the encapsulation layer 350 shown in FIG. 3D may correspond to the substrate 100, the first conductive lines 110, the memory cell 120, the lower electrode layer 121, the selector layer 122, the middle electrode layer 123, the variable resistance layer 124, the upper electrode layer 125, the second conductive lines 130, the protection layer 140 and the encapsulation layer 150 shown in FIG. 1B, respectively.

In the implementation shown in FIGS. 3A to 3D, the selector layer 322 is disposed under the variable resistance layer 324. However, the relative positions of the selector layer 322 and the variable resistance layer 324 may be reversed.

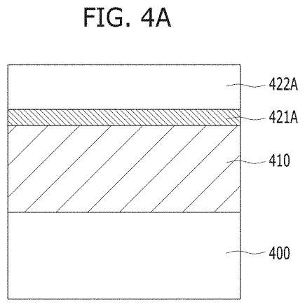

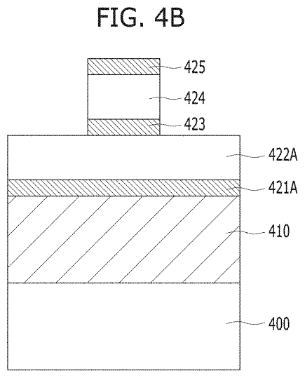

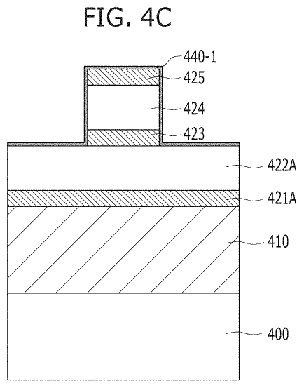

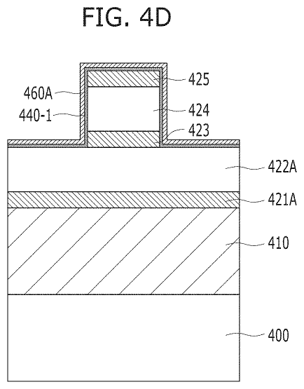

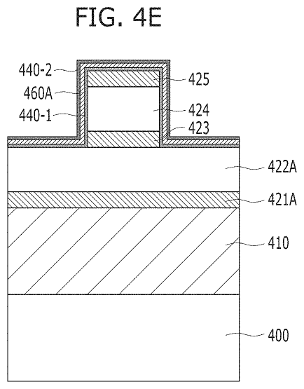

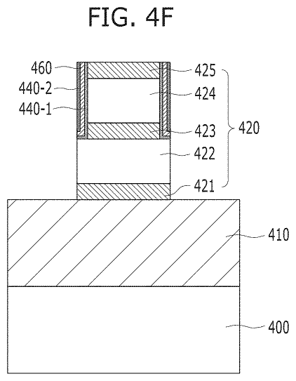

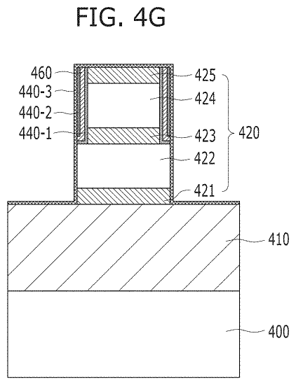

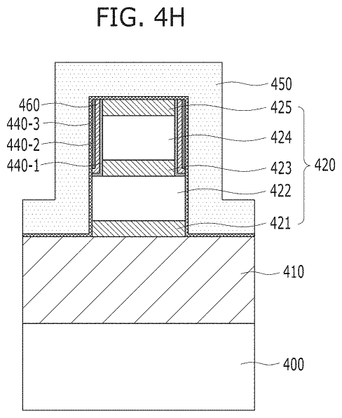

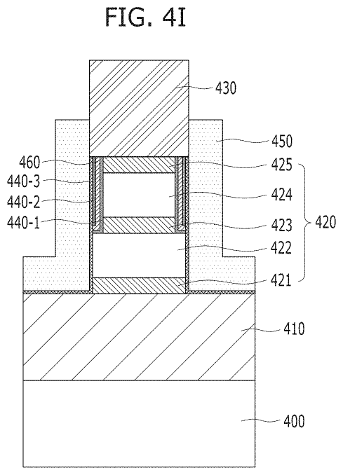

FIGS. 4A to 4I are cross-sectional views illustrating another example method for fabricating a semiconductor device based on some implementations of the disclosed technology.

The implementation shown in FIG. 4A to 4I may be similar to the implementation shown in FIGS. 3A to 3D except that a sidewall spacer layer 460, a first sub protection layer 440-1 and a second sub protection layer 440-2 are formed. The detailed descriptions similar to those described in the implementation of FIGS. 3A to 3D will be omitted.

Referring to FIG. 4A, first conductive lines 410 may be formed on a substrate 400 in which a predetermined structure is formed.

A material layer 421A for a lower electrode layer and a material layer 422A for a selector layer may be sequentially formed on the first conductive lines 410.

Referring to FIG. 4B, a middle electrode layer 423, a variable resistance layer 424 and an upper electrode layer 425 may be formed on the material layer 422A.

The middle electrode layer 423, the variable resistance layer 424 and the upper electrode layer 425 may be formed by forming a material layer for the middle electrode layer 423, a material layer for the variable resistance layer 424 and a material layer for the upper electrode layer 425 and etching the material layers using a mask pattern.

Referring to FIG. 4C, a first sub protection layer 440-1 may be formed on the structure of FIG. 4B by performing a helium treatment process on the structure of FIG. 4B. The first sub protection layer 440-1 may be formed on side surfaces of the middle electrode layer 423, the variable resistance layer 424 and the upper electrode layer 425, on the upper electrode layer 425, and on the material layer 422A.

The helium treatment process may be performed under a condition of a flow rate of a helium gas of 5-1000 sccm, a RF power of 100-5000 W, and a temperature of 25-350° C. In some implementations, the helium treatment process may include applying helium to the surface of a certain material layer under the conditions discussed above.

The first sub protection layer 440-1 may be formed by performing the helium treatment process to modify the surfaces to be very flat. The plasma generated by a helium gas may induce atomic migration on the surfaces of the middle electrode layer 423, the variable resistance layer 424 and the upper electrode layer 425 to modify the surfaces to be very flat, thereby forming the first sub protection layer 440-1. The physical thickness of the first sub protection layer 440-1 may be very small.

Referring to FIG. 4D, an initial sidewall spacer layer 460A may be conformally formed on the structure of FIG. 4C.

The initial sidewall spacer layer 460A may serve to protect the middle electrode layer 423, the variable resistance layer 424 and the upper electrode layer 425 during a subsequent process of patterning the material layer 422A and the material layer 421A. After the patterning process, the initial sidewall spacer layer 460A may remain as a sidewall spacer layer (see, reference numeral 460 of FIG. 4F).

The initial sidewall spacer layer 460A may include a dielectric material. The dielectric material may include an oxide, a nitride, or a combination thereof.

Referring to FIG. 4E, a second sub protection layer 440-2 may be formed by performing a helium treatment on the structure of FIG. 4D. The second sub protection layer 440-2 may be formed on the initial sidewall spacer layer 460A. That is, the helium treatment process for forming the second sub protection layer 440-2 may be performed after forming the initial sidewall spacer layer 460A. The physical thickness of the second sub protection layer 440-2 may be very small.

The helium treatment may be performed under a condition of a flow rate of a helium gas of 5-1000 sccm, a RF power of 100-5000 W, and a temperature of 25-350° C. In some implementations, the helium treatment process may include applying helium to the surface of a certain material layer under the condition discussed above.

Referring to FIG. 4F, a lower electrode layer 421 and a selector layer 422 may be formed by patterning the material layer 422A and the material layer 421A using spacer pattering technology (SPT). The initial sidewall spacer layer 460A may remain as the sidewall spacer layer 460. A portion of the first sub protection layer 440-1, a portion of the initial sidewall spacer layer 460A and a portion of the second sub protection layer 440-2 disposed on the upper electrode layer 425 may be removed. That is, by the pattering process of FIG. 4F, the first sub protection layer 440-1 may be disposed on the side surfaces of the middle electrode layer 423, the variable resistance layer 424 and the upper electrode layer 425, the sidewall spacer layer 460 may be disposed on the side surfaces of the first sub protection layer 440-1, and the second sub protection layer 440-2 may be disposed on the side surfaces of the sidewall spacer layer 460.

As such, a memory cell 420 including the lower electrode layer 421, the selector layer 422, the middle electrode layer 423, the variable resistance layer 424 and the upper electrode layer 425 which are sequentially stacked may be formed.

Referring to FIG. 4G, a third protection layer 440-3 may be formed by performing a helium treatment process on the structure of FIG. 4F. The third protection layer 440-3 may be formed on side surfaces of the lower electrode layer 421, the selector layer 422 and the second sub protection layer 440-2, and upper surfaces of the upper electrode layer 425, the first sub protection layer 440-1, the sidewall spacer layer 460, the second sub protection layer 440-2, and the first conductive lines 410. That is, the helium treatment process for forming the third protection layer 440-3 may be performed after etching the material layer 422a and the material layer 421A using the initial sidewall spacer layer 460A.

The helium treatment process may be performed under a condition of a flow rate of a helium gas of 5-1000 sccm, a RF power of 100-5000 W, and a temperature of 25-350° C. In some implementations, the helium treatment process may include applying helium to the surface of a certain material layer under the condition discussed above.

Referring to FIG. 4H, an encapsulation layer 450 may be conformally formed on the structure of FIG. 4G.

The encapsulation layer 450 may include a dielectric material. The dielectric material may include an oxide, a nitride, or a combination thereof. For example, the encapsulation layer 450 may include SiO₂, SiN₄, SiOCN, SiON, or a combination thereof.

Referring to FIG. 4I, second conductive lines 430 may be formed on the memory cell 420. At this time, a portion of the third protection layer 440-3 and a portion of the encapsulation layer 450 on the upper electrode layer 425, the first sub protection layer 440-1, the sidewall spacer layer 460 and the second sub protection layer 440-2 may be removed.

Through the processes as described above, the semiconductor device including the first conductive lines 410, the memory cell 420, the second conductive lines 430, the first sub protection layer 440-1, the second sub protection layer 440-2, the third protection layer 440-3, the encapsulation layer 450 and the sidewall spacer layer 460 may be formed. The memory cell 420 may include the lower electrode layer 421, the selector layer 422, the middle electrode layer 423, the variable resistance layer 424 and the upper electrode layer 425 which are sequentially stacked.

In accordance with the implementation, the protection layer 440-3 may be formed on the entire side surfaces of the memory cell 420 and the upper surface of the first conductive lines 410. It is possible to reduce the adverse effect of the encapsulation layer 450 on the selector layer 422 or the variable resistance layer 424, thereby preventing deterioration of characteristics of the selector layer 422 and the variable resistance layer 424 and maintaining the original characteristics of the selector layer 422 and the variable resistance layer 424.

The semiconductor device in accordance with the implementation may further include the first sub protection layer 440-1 and the second sub protection layer 440-2 in addition to the third protection layer 440-3. The first sub protection layer 440-1 and the second sub protection layer 440-2 may be formed on the side surface of an upper portion of the memory cell 420. That is, the first sub protection layer 440-1 may be formed on the side surfaces of the middle electrode layer 423, the variable resistance layer 424 and the upper electrode layer 425, and the second sub protection layer 440-2 may be formed on the side surfaces of the sidewall spacer layer 460. The first sub protection layer 440-1 and the second sub protection layer 440-2 may further enhance the protective effect on the variable resistance layer 424 and prevent material diffusion from the outside that may cause deterioration of characteristics of the variable resistance layer 424. Therefore, even if the encapsulation layer 450 may deteriorate characteristics of the variable resistance layer 424, it is possible to prevent formation of the dead layers in the variable resistance layer 424, maintain the crystal structure intact, and improve reliability by strengthening resistance.

Further, intermixing between the memory cell 420 and the encapsulation layer 450 may be suppressed by the first sub protection layer 440-1, the second sub protection layer 440-2 and the third protection layer 440-3.

In the implementation, the first sub protection layer 440-1, the second sub protection layer 440-2 and the third protection layer 440-3 are formed. In another implementation, at least one of the first sub protection layer 440-1, the second sub protection layer 440-2 and the third protection layer 440-3 may be omitted. In some implementations, the semiconductor device may include the first sub protection layer 440-1 and the second sub protection layer 440-2. In this case, since the variable resistance layer 424 may be sufficiently protected by the first sub protection layer 440-1 and the second sub protection layer 440-2, the encapsulation layer 450 may be selected only considering prevention of deterioration of the variable resistance layer 424. In some implementations, the semiconductor device may include the first sub protection layer 440-1 and the third protection layer 440-3. In some implementations, the semiconductor device may include the second sub protection layer 440-2 and the third protection layer 440-3.

In the implementation shown in FIGS. 4A to 4I, the selector layer 422 may be disposed below the variable resistance layer 424.

However, the relative positions of the selector layer 422 and the variable resistance layer 424 may be reversed. In some implementations, the selector layer 422 may be disposed over the variable resistance layer 424. In this case, it is possible to enhance the protective effect of the selector layer 422 by the first sub protection layer 440-1 and the second sub protection layer 440-2.

The substrate 400, the first conductive lines 410, the memory cell 420, the lower electrode layer 421, the selector layer 422, the middle electrode layer 423, the variable resistance layer 424, the upper electrode layer 425, the second conductive lines 430, the third protection layer 440-3 and the encapsulation layer 450 shown in FIG. 4I may correspond to the substrate 100, the first conductive lines 110, the memory cell 120, the lower electrode layer 121, the selector layer 122, the middle electrode layer 123, the variable resistance layer 124, the upper electrode layer 125, the second conductive lines 130, the protection layer 140 and the encapsulation layer 150 shown in FIG. 1B, respectively, and the substrate 300, the first conductive lines 310, the memory cell 320, the lower electrode layer 321, the selector layer 322, the middle electrode layer 323, the variable resistance layer 324, the upper electrode layer 325, the second conductive lines 330, the protection layer 340 and the encapsulation layer 350 shown in FIG. 3D, respectively.

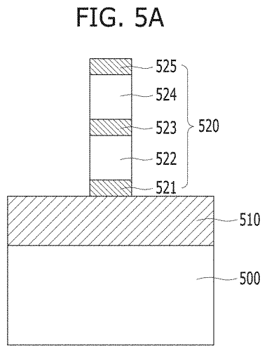

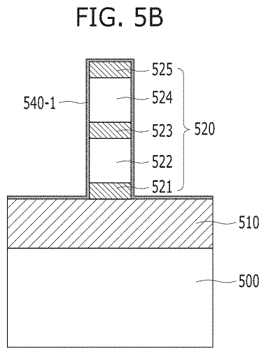

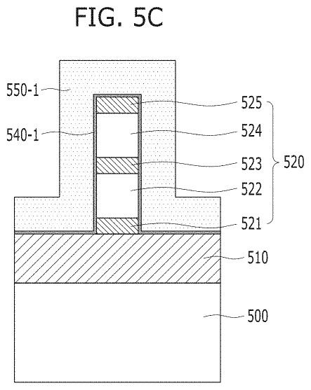

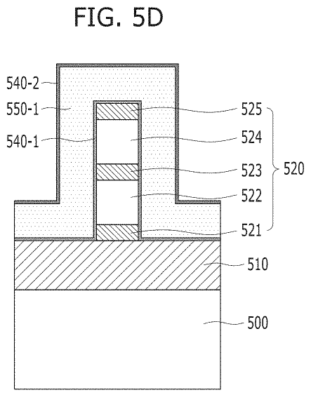

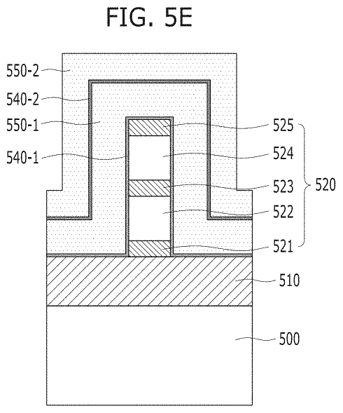

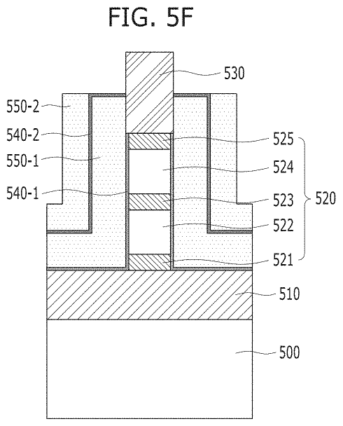

FIGS. 5A to 5F are cross-sectional views illustrating another example method for fabricating a semiconductor device based on some implementations of the disclosed technology.

The implementation shown in FIGS. 5A to 5F may be similar to the implementation shown in FIG. 3A to 3D except that two encapsulation layers 550-1 and 550-2 and two protection layers 540-1 and 540-2 are formed. The detailed descriptions similar to those described in the implementation of FIG. 3A to 3D will be omitted.

Referring to FIG. 5A, first conductive lines 510 may be formed on a substrate 500 in which a predetermined structure is formed.

A memory cell 520 may be formed on the first conductive lines 510. The memory cell 520 may be formed by forming a material layer for a lower electrode layer 521, a material layer for a selector layer 522, a material layer for a middle electrode layer 523, a material layer for a variable resistance layer 524 and a material layer for an upper electrode layer 525 and etching the material layers using a mask pattern.

Referring to FIG. 5B, a helium treatment process may be performed on the memory cell 520.

The helium treatment process may be performed under a condition of a flow rate of a helium gas of 5-1000 sccm, a RF power of 100-5000 W, and a temperature of 25-350° C. In some implementations, the helium treatment process may include applying helium to the surface of a certain material layer under the condition discussed above.

By performing the helium treatment on the memory cell 520, plasma generated from a helium gas may induce the movement of atoms on the surface of the memory cell 520 so that the surface morphology or profile may become very flattened. The layer obtained by modifying the surface morphology or profile by the helium treatment may be referred to as a first protection 540-1. The physical thickness of the first protection 540-1 may be very thin. By modifying the surface morphology of the memory cell 520 through the helium treatment, it is possible to prevent diffusion of atoms from the outside to the memory cell 520 and energy transfer to the memory cell 520 by the RF power in a subsequent process of forming encapsulating layers (see, reference numeral 550-1 of FIG. 5C and reference numeral 550-2 of FIG. 5E).

The first protection 540-1 may be formed on side surfaces and an upper surface of the memory cell 520 and an upper surface of the first conductive lines 510.

Referring to FIG. 5C, the first encapsulation layer 550-1 may be conformally formed on the structure of FIG. 5B.

The first encapsulation layer 550-1 may include a dielectric material. The dielectric material may include an oxide, a nitride, or a combination thereof. For example, the first encapsulation layer 550-1 may include SiO₂, SiN₄, SiOCN, SiON, or a combination thereof.

Referring to FIG. 5D, a helium treatment process may be performed on the structure of FIG. 5D.

The helium treatment process may be performed under a condition of a flow rate of a helium gas of 5-1000 sccm, a RF power of 100-5000 W, and a temperature of 25-350° C. In some implementations, the helium treatment process may include applying helium to the surface of a certain material layer under the condition discussed above.

By performing the helium treatment process, plasma generated from a helium gas may induce the movement of atoms on the surface of the first encapsulation layer 550-1 to modify the surface morphology to be very flat. The layer obtained by modifying the surface morphology or profile by the helium treatment may be referred to as a second protection layer 540-2. The second protection layer 540-2 may be conformally formed on the first encapsulation layer 550-1. The physical thickness of the second protection layer 540-2 may be very thin. By modifying the surface morphology of the first encapsulation layer 550-1 through the helium treatment process, it is possible to prevent diffusion of atoms from the outside to the memory cell 520 and energy transfer to the memory cell 520 by the RF power in a subsequent process of forming the second encapsulation layer 550-2.

Referring to FIG. 5E, the second encapsulation layer 550-2 may be conformally formed on the structure of FIG. 5G.

The second encapsulation layer 550-2 may include a dielectric material. The dielectric material may include an oxide, a nitride, or a combination thereof. For example, the second encapsulation layer 550-2 may include SiO₂, SiN₄, SiOCN, SiON, or a combination thereof.

The first encapsulation layer 550-1 and the second encapsulation layer 550-2 may include different materials from each other. In some implementations, the first encapsulation layer 550-1 may include an oxide, while the second encapsulation layer 550-2 may include a nitride. In some implementations, the first encapsulation layer 550-1 may include a nitride, while the second encapsulation layer 550-2 may include an oxide.

Referring to FIG. 5F, second conductive lines 530 may be formed on the memory cell 520. At this time, a portion of the first protection 540-1, a portion of the first encapsulation layer 550-1, a portion of the second protection layer 540-2 and a portion of the second encapsulation layer 550-2 disposed on the upper electrode layer 525 may be removed.

Through the processes as described above, the semiconductor device including the first conductive lines 510, the memory cell 520, the second conductive lines 530, the first protection 540-1, the first encapsulation layer 550-1, the second protection layer 540-2 and the second encapsulation layer 550-2 may be formed. The memory cell 520 may include the lower electrode layer 521, the selector layer 522, the middle electrode layer 523, the variable resistance layer 524 and the upper electrode layer 525 which are sequentially stacked. The first protection 540-1 may be disposed on the side surfaces of the memory cell 520 and the upper surface of the first conductive lines 510, and the second protection layer 540-2 may be conformally disposed on the first encapsulation layer 550-1.

In accordance with the implementation, the first protection 540-1 and the second protection layer 540-2 in which the surface morphology is modified may be formed by performing the helium treatment process before forming the first encapsulation layer 550-1 and the second encapsulation layer 550-2. Thus, it is possible to reduce the adverse effect of the first encapsulation layer 550-1 and the second encapsulation layer 550-2 on the selector layer 522 or the variable resistance layer 524. Therefore, it is possible to prevent deterioration of characteristics of the selector layer 522 and the variable resistance layer 524 and maintain the original characteristics of the selector layer 522 and the variable resistance layer 524. By performing the helium treatment process before forming the first encapsulation layer 550-1, dopant loss in the selector layer 522 may be reduced or prevented during forming the first encapsulation layer 550-1 and the second encapsulation layer 550-2 in the subsequent process. Further, it is possible to prevent diffusion of materials to the variable resistance layer 524. Accordingly, formation of the dead layers in the variable resistance layer 524 can be prevented, the crystal structure can be completely maintained, and reliability can be improved by strengthening resistance. Moreover, it is possible to reduce an operation current and prevent deformation of the selector layer 322. In addition, intermixing between the memory cell 520 and the first encapsulation layer 550-1 or the second encapsulation layer 550-2 can be suppressed by the first protection 540-1, and intermixing between the memory cell 520 or the first encapsulation layer 550-1 and the second encapsulation layer 550-2 can be suppressed by the second protection layer 540-2.

The substrate 500, the first conductive lines 510, the memory cell 520, the lower electrode layer 521, the selector layer 522, the middle electrode layer 523, the variable resistance layer 524, the upper electrode layer 525, the second conductive lines 530, the first and second protection layers 540-1 and 540-2 and the first and second encapsulation layers 550-1 and 550-2 shown in FIG. 5F may correspond to the substrate 100, the first conductive lines 110, the memory cell 120, the lower electrode layer 121, the selector layer 122, the middle electrode layer 123, the variable resistance layer 124, the upper electrode layer 125, the second conductive lines 130, the protection layer 140 and the encapsulation layer 150 shown in FIG. 1B, respectively, and the substrate 300, the first conductive lines 310, the memory cell 320, the lower electrode layer 321, the selector layer 322, the middle electrode layer 323, the variable resistance layer 324, the upper electrode layer 325, the second conductive lines 330, the protection layer 340 and the encapsulation layer 350 shown in FIG. 3D, respectively.

In the implementation shown in FIGS. 5A to 5F, the selector layer 522 is disposed under the variable resistance layer 524.

However, the relative positions of the selector layer 522 and the variable resistance layer 524 may be reversed.

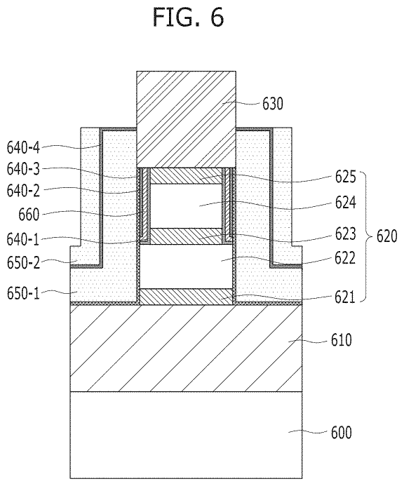

FIG. 6 illustrate a semiconductor device based on some implementations of the disclosed technology. The detailed descriptions similar to those described in the implementations of FIGS. 4A to 4I and FIGS. 5A to 5F.

The semiconductor device shown in FIG. 6 may include first conductive lines 610, a memory cell 620, second conductive lines 630, a first sub protection layer 640-1, a sidewall spacer layer 660, a second sub protection layer 640-2, a first protection layer 640-3, a first encapsulation layer 650-1, a second protection layer 640-4 and a second encapsulation layer 650-2. The memory cell 620 may include a lower electrode layer 621, a selector layer 622, a middle electrode layer 623, a variable resistance layer 624 and an upper electrode layer 625 which are sequentially stacked. The first sub protection layer 640-1 may be disposed on side surfaces of the middle electrode layer 623, the variable resistance layer 624 and the upper electrode layer 625. The sidewall spacer layer 660 may be disposed on side surfaces of the first sub protection layer 640-1, and the second sub protection layer 640-2 may be disposed on side surfaces of the sidewall spacer layer 660. The first protection layer 640-1 may be disposed on side surfaces of the memory cell 620 and an upper surface of the first conductive lines 610. The second protection layer 640-2 may be conformally disposed on the first encapsulation layer 650-1.

The semiconductor device may be formed by forming the first conductive lines 610, the memory cell 620, the first sub protection layer 640-1, the sidewall spacer layer 660, the second sub protection layer 640-2, the first protection layer 640-3 and the first encapsulation layer 650-1 over the substrate 600 using a similar method to those of FIGS. 4A to 4H, and forming the second protection layer 640-4, the second encapsulation layer 650-2 and the second conductive lines 630 using a similar method to those of FIGS. 5D to 5F.

In accordance with the implementation, the first protection layer 640-3 may be formed by performing a helium treatment process before forming the first encapsulation layer 650-1 and the second protection layer 640-4 may be formed by performing a helium treatment process before forming the second encapsulation layer 650-2. Thus, it is possible to reduce or minimize the adverse effect of the first and second encapsulation layers 650-1 and 650-2 on the selector layer 622 or the variable resistance layer 624, thereby preventing deterioration of characteristics of the selector layer 622 and the variable resistance layer 624 and maintaining the original characteristics of the selector layer 622 and the variable resistance layer 624. Further, in the implementation, the semiconductor device may further include the first sub protection layer 640-1 and the second sub protection layer 640-2 disposed on side surfaces of an upper portion of the memory cell 620. The first sub protection layer 640-1 and the second sub protection layer 640-2 may enhance the protective effect on the variable resistance layer 624 to prevent material diffusion that may cause deterioration of the variable resistance layer 624.

In the implementation, the first sub protection layer 640-1, the second sub protection layer 640-2, the first protection layer 640-3 and the second protection layer 640-4 are formed. However, in some implementations, at least one of the first sub protection layer 640-1, the second sub protection layer 640-2, the first protection layer 640-3 and the second protection layer 640-4 may be omitted.

In the implementation shown in FIG. 6, the selector layer 622 may be disposed below the variable resistance layer 624. However, the relative positions of the selector layer 622 and the variable resistance layer 424 may be reversed. In some implementations, the selector layer 622 may be disposed over the variable resistance layer 624. In this case, it is possible to enhance the protective effect of the selector layer 622 by the first sub protection layer 640-1 and the second sub protection layer 640-2.

Only a few embodiments and examples are described. Enhancements and variations of the disclosed embodiments and other embodiments can be made based on what is described and illustrated in this patent document.

What is claimed is:

1. A semiconductor device comprising:
a memory cell disposed over a substrate and including a variable resistance layer and a selector layer;
a protection layer disposed on side surfaces of the memory cell and an upper surface of the substrate on which the memory cell is not disposed; and
a first encapsulation layer disposed on the memory cell and the protection layer,
wherein the protection layer includes a treated surface that is modified by a material including helium.

2. The semiconductor device according to claim 1, wherein the protection layer is structured to prevent material diffusion to the variable resistance layer and prevent energy transfer to the selector layer.

3. The semiconductor device according to claim 1, wherein the variable resistance layer includes a magnetic tunnel junction (MTJ) structure, and the selector layer includes a dielectric material and a dopant.

4. The semiconductor device according to claim 1, further comprising:
a sidewall spacer layer disposed between the variable resistance layer and the protection layer; and
at least one of a first sub protection layer or a second sub protection layer, wherein the first sub protection layer is disposed between the variable resistance layer and the sidewall spacer layer, and the second sub protection layer is disposed between the sidewall spacer layer and the protection layer,
wherein the first sub protection layer and the second sub protection layer include a treated surface that is modified by a material including helium.

5. The semiconductor device according to claim 1, further comprising:
an additional protection layer disposed on the first encapsulation layer; and
a second encapsulation layer disposed on the additional protection layer,
wherein the additional protection layer includes a treated surface that is modified by a material including helium.

6. The semiconductor device according to claim 5, wherein one of the first encapsulation layer and the second encapsulation layer includes an oxide, and the other of the first encapsulation layer and the second encapsulation layer includes an oxide includes a nitride.

7. A method for fabricating a semiconductor device comprising:
forming a memory cell over a substrate, the memory cell including a variable resistance layer and a selector layer;
forming a protection layer on the memory cell and the substrate on which the memory cell is not disposed by performing a first helium treatment process on the memory cell; and
forming a first encapsulation layer on the memory cell and the protection layer.

8. The method according to claim 7, wherein the protection layer includes a treated surface that is modified by the first helium treatment process.

9. The method according to claim 7, wherein the protection layer is structured to prevent material diffusion to the variable resistance layer and prevent energy transfer to the selector layer.

10. The method according to claim 7, wherein the variable resistance layer includes a magnetic tunnel junction (MTJ) structure, and the selector layer includes a dielectric material and a dopant.

11. The method according to claim 7, wherein the first helium treatment process is performed under a condition of a flow rate of a helium gas of 5 to 1000 sccm, a RF power of 100 to 5000 W, and a temperature of 25 to 350° C.

12. The method according to claim 7, further comprising:
forming an additional protection layer on the first encapsulation layer by performing a second helium treatment process on the first encapsulation layer; and
forming a second encapsulation layer on the additional protection layer.

13. The method according to claim 12, wherein one of the first encapsulation layer and the second encapsulation layer includes an oxide, and the other of the first encapsulation layer and the second encapsulation layer includes a nitride.

14. The method according to claim 12, wherein the additional protection layer includes a treated surface that is modified by the second helium treatment process.

15. The method according to claim 12, wherein the second helium treatment process is performed under a condition of a flow rate of a helium gas of 5 to 1000 sccm, a RF power of 100 to 5000 W, and a temperature of 25 to 350° C.
